(19) United States
(12) Patent Application Publication
(10) Pub. No.: US 2002/0048879 A1
(43) Pub. Date: Apr. 25, 2002

(54) Structure of a lower electrode of a capacitor and a process for fabricating the same

(75) Inventor: Chuan-Fu Wang, Taipei Hsien (TW)

Correspondence Address: CHARLES C.H. WU, 7700 IRVINE CENTER DRIVE, SUITE 710, IRVINE, CA, 92618-3043, US

(73) Assignee: UNITED MICROELECTRONICS CORP.

(21) Appl. No.: 09/906,461

(22) Filed: Jul. 16, 2001

Related U.S. Application Data
(62) Division of application No. 09/696,472, filed on Oct. 24, 2000, now abandoned.

(51) Int. Cl. G06F 17/50; H01L 21/8242; H01L 21/20

(52) U.S. Cl. 438/253; 438/240; 438/239; 438/255; 438/396; 438/398

(57) ABSTRACT

A process for fabricating a lower electrode of a capacitor on a substrate having a dielectric layer formed thereon. A node contact opening is first formed in the dielectric layer to expose a part of a conductive portion on the substrate. A node contact is then formed in the node contact opening such that the node contact protrudes from the dielectric layer. Subsequently, an insulating layer and a conductive layer are formed in sequence on the dielectric layer and the node contacts. The conductive layer and the insulating layer are patterned in sequence to expose a part of the node contacts and leave the residual insulating layer as a protruding part and a link layer, in which the protruding part is located on a part of the node contacts and a part of the dielectric layer, and the link layer is located on the dielectric layer outside the node contacts, serving as a link for the dielectric layer and the protruding part. A conductive spacer is formed on the sidewall of the conductive layer and the protruding part for electric contact with the node contact, in which the conductive spacer is combined with the conductive layer as a lower electrode of a capacitor. A structure obtained by the above process is also provided.

### BACKGROUND OF THE INVENTION

1. Field of the Invention

The present invention relates to a structure of an integrated circuit (IC) and a process for fabricating the same. More specifically, the present invention relates to a structure of a lower electrode of a capacitor and a process for fabricating the same.

2. Description of the Related Art

A capacitor is a part for storage of information in the dynamic random access memory (DRAM). Information in each memory cell is determined by the charges in the capacitor. With relatively reduced size of a current memory cell, it is common to increase the height of the lower electrode of the capacitor to increase the surface area thereof such that the capacitance of the capacitor is enhanced to reduce the misinterpretation of the stored information and refreshing of information in the memory cells is reduced to raise the operational efficiency.

Referring to FIG. 1, a conventional structure of a lower electrode of a capacitor is shown. In the structure, a dielectric layer 120 is first formed on the substrate 100. A polysilicon node contact 140 is formed in the dielectric layer 120. The node contact 140 is in electric contact with the substrate 100. Then, a polysilicon layer (not shown) is formed on the dielectric layer 120 and the node contact 140 and then is defined to form a lower electrode 180 of a capacitor. The lower electrode 180 is rinsed with RCA solution to clean the surface thereof before a subsequent treatment is performed. The RCA solution includes water, sulfuric acid (H₂SO₄) and hydrogen peroxide (H₂O₂). Hemispherical silicon grains 190 are formed on the surface of the lower electrode 180 to increase the surface area of the lower electrode 180.

However, as size of a memory cell decreases, the height of the lower electrode 180 must also increase to provide sufficient surface area. Therefore, when the lower electrode 180 is cleaned with RCA solution, the lower electrode 180 easily peels from the memory cell, resulting in reduced yield.

### SUMMARY OF INVENTION

Therefore, it is one object of the present invention to provide a process for fabricating a lower electrode of a capacitor applicable on a substrate on which a dielectric layer is formed. A node contact opening is first formed in the dielectric layer to expose part of a conductive portion on the substrate. A node contact is then formed in the node contact opening so that the node contact protrudes out of the dielectric layer. Subsequently, an insulating layer and a conductive layer are covered in sequence on the dielectric layer and the node contacts. The conductive layer and the insulating layer are patterned in sequence to expose part of the node contacts and leave the remaining insulating layer. The remaining insulating layer includes a protruding part and a link layer. The protruding part is located on a part of the node contacts and a part of the dielectric layer, and the link layer is located on the dielectric layer outside the node contacts, serving as a link for the dielectric layer and the protruding part. A conductive spacer is formed on the sidewall of the conductive layer and the protruding part for electric contact with the node contact, in which the conductive spacer is combined with the conductive layer to serve as a lower electrode of a capacitor.

Further, it is another object of the present invention to provide a structure of a lower electrode of a capacitor applicable on a substrate on which a dielectric layer having at least a node contact opening to expose part of conductive portion on the substrate is formed. A node contact is formed in the node contact opening and is in electric contact with the conductive portion. The node contact protrudes out of the dielectric layer. A protruding part is positioned on part of the node contact and part of the dielectric layer. A conductive is located on the protruding part and a link layer is located on the dielectric layer outside the node contact to link the dielectric layer and the protruding part. The link layer is formed of the same material with the protruding part and used to link the dielectric layer and the protruding part. A conductive spacer is located on the sidewall of the conductive layer and the protruding part, and is in electric contact with the node contact. The conductive spacer and the conductive layer together form a lower electrode.

In the structure of a lower electrode of a capacitor and the process therefor according to the present invention as set forth above, the conductive portion is a source/drain region of a metal oxide semiconductor or a landed via. The landed via is in electric contact with a source/drain region of a metal oxide semiconductor. Furthermore, hemispherical silicon grains can be formed on the surface of the lower electrode to further increase the surface area of the lower electrode.

As mentioned above, in the structure of the lower electrode obtained by the process according one preferred example of the present invention, the body of the lower electrode (the polysilicon spacers) is formed on a sidewall of a protruding part. The adhesion of the protruding part is increased by the link layer. Therefore, compared with the conventional lower electrode of a capacitor (FIG. 1), the lower electrode is rather rigid and peeling does not occur easily when rinsing with RCA solution.

### BRIEF DESCRIPTION OF THE DRAWINGS

It is to be understood that both the foregoing general description and the following detailed description are exemplary, and are intended to provide further explanation of the invention as claimed.

The accompanying drawings are included to provide a further understanding of the invention, and are incorporated in and constitute a part of this specification. The drawings illustrate embodiments of the invention and, together with the description, serve to explain the principle of the invention. In the drawings,

FIG. 1 is a schematic, cross-sectional view of a conventional structure of a lower electrode of a capacitor; and

FIG. 2A-2F are schematic, cross-section views illustrating the process for fabricating a lower electrode of a capacitor according to one preferred example of the present invention.

### DESCRIPTION OF THE PREFERRED EMBODIMENT

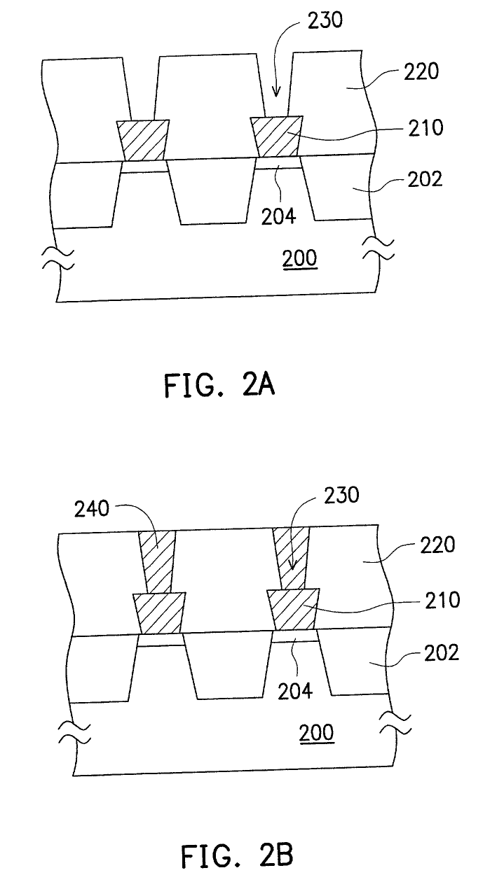

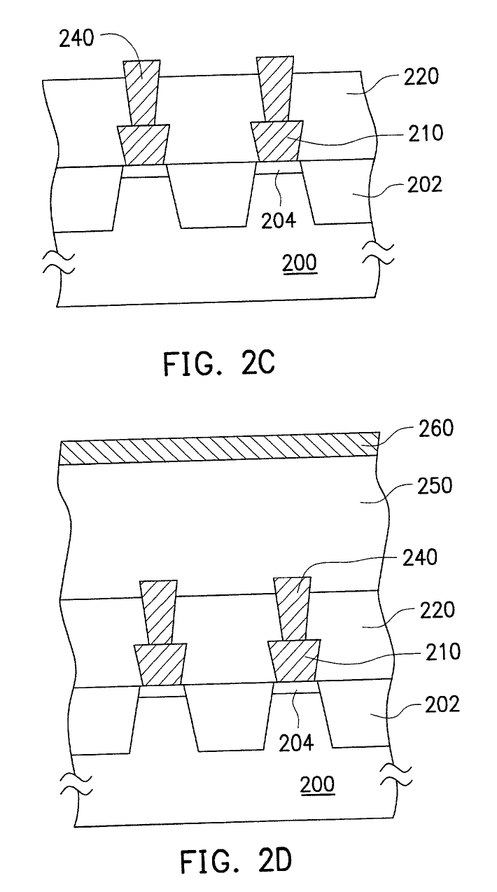

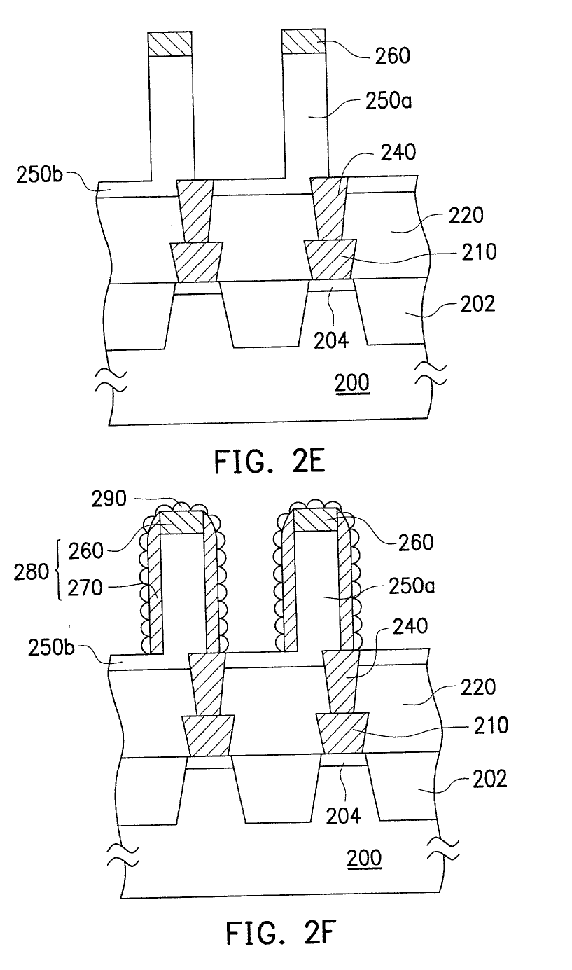

Referring to FIG. 2A, a substrate 200 is provided. A plurality of isolating layers 202 and a plurality of drain regions 204 therebetween are formed in the substrate 200. The drain region 204 is a portion of a metal oxide semiconductor (not shown). Landed vias 210 having electric contacts are formed on the drain regions 204. A dielectric layer 220, such as a silicon oxide layer, is formed on the substrate 200. The dielectric layer 220 is patterned to form node contact openings 230.

Referring to FIG. 2B, a layer of conductive material (not shown) used to form node contacts 240 in FIG. 2B is covered on the dielectric layer 220 and filled the node contact openings 230. The conductive material can be polysilicon, for example. The conductive material outside the node contact openings 230 is removed by etching back or chemical mechanical polishing to form node contacts 240.

Referring to FIG. 2C, a part of the dielectric layer 220 is removed by etching back such that the node contacts 240 protrude from the dielectric layer 220.

Referring to FIG. 2D, an insulating layer 250 and a polysilicon layer 260 are deposited in sequence over the substrate 200. The insulating layer 260 can be made of silicon oxide, for example.

Referring to FIG. 2E, the conductive layer 260 and the insulating layer 250 are patterned to expose a part of the node contacts 240 and leave the remaining insulating layer 250, which includes as a protruding part 250a and a link layer 250b. The protruding part 250a is located on a part of the node contacts 240 and a part of the dielectric layer 220. The link layer 250b is located on the dielectric layer 220 outside the node contacts 240. The link layer 250b serves as a linker for the dielectric layer 220 and the protruding part 250a.

Referring to FIG. 2F, polysilicon spacers 270 are formed on the sidewalls of the protruding part 250a and the patterned polysilicon layers 260 for electric contact with the node contacts 240. The polysilicon spacers 270 and the conductive layer 260 are combined to serve as a lower electrode 280 of a capacitor. Then, hemispherical silicon grains 290 can be formed on the surface of the lower electrode 280 to further increase the surface area of the lower electrode 280.

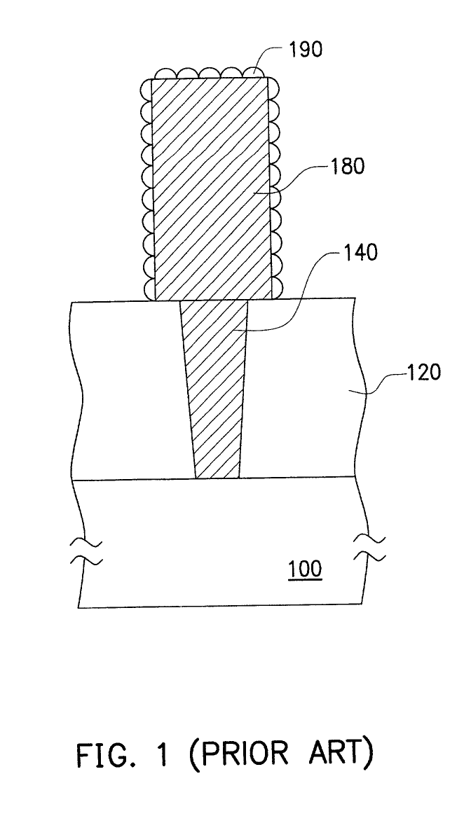

As mentioned above, in the structure of the lower electrode 280 obtained by the process according one preferred example of the present invention, the body of the lower electrode 280 (the polysilicon spacers 270) is formed on the sidewalls of the protruding part 250a (FIG. 2F). The adhesion is increased by the protruding part 250a accompanying the link layer 250b (FIGS. 2E and 2F). Therefore, compared with the conventional lower electrode 180 of a capacitor (FIG. 1), the lower electrode 280 is rather rigid so that peeling does not occur easily when rinsing with RCA solution.

It will be apparent to those skilled in the art that various modifications and variations can be made to the structure of the present invention without departing from the scope or spirit of the invention. In view of the forgoing, it is intended that the present invention cover modification and variation of this invention provided they fall within the scope of the following claims and their equivalents.

What is claimed is:

1. A process for fabricating a lower electrode of a capacitor applicable on a substrate on which a dielectric layer is formed, comprising:
forming a node contact opening in the dielectric layer to expose a part of a conductive portion on the substrate;
forming a node contact in the node contact opening, whereby the node contact protrudes from the dielectric layer;
forming an insulating layer and a conductive layer in sequence on the dielectric layer and the node contacts;
patterning the conductive layer and the insulating layer in sequence to expose a part of the node contacts and leave the residual insulating layer as a protruding part and a link layer, in which the protruding part is located on a part of the node contacts and a part of the dielectric layer, and the link layer is located on the dielectric layer outside the node contacts, serving as a link for the dielectric layer and the protruding part; and
forming a conductive spacer on a sidewall of the conductive layer and the protruding part for electric contact with the node contact, in which the conductive spacer is combined with the conductive layer to serve as a lower electrode of a capacitor.

2. The process for fabricating a lower electrode of a capacitor of claim 1, wherein forming a node contact in the node contact opening whereby the node contact protrudes from the dielectric layer further comprises:
covering the dielectric layer on which the node contact opening is formed with a layer of conductive material and filling the node contact opening;
removing conductive material outside the node contact opening by etching back or chemical mechanical polishing to form a node contact with a residual conductive material; and
etching back a part of the dielectric layer whereby the node contact protrudes from the dielectric layer.

3. The process for fabricating a lower electrode of a capacitor of claim 2, wherein the conductive material is polysilicon.

4. The process for fabricating a lower electrode of a capacitor of claim 1, further comprising forming a plurality of hemispherical silicon grains on a surface of the lower electrode after the lower electrode is formed.

5. The process for fabricating a lower electrode of a capacitor of claim 1, wherein the conductive portion includes a source/drain region which is a part of a metal oxide semiconductor.

6. The process for fabricating a lower electrode of a capacitor of claim 1, wherein the conductive portion includes a landed via in electric contact with a source/drain region which is a part of a metal oxide semiconductor.

7. The process for fabricating a lower electrode of a capacitor of claim 1, wherein the insulating layer is made of silicon oxide.

8. The process for fabricating a lower electrode of a capacitor of claim 1, wherein the conductive layer is made of polysilicon.

9. The process for fabricating a lower electrode of a capacitor of claim 1, wherein the conductive spacer is made of polysilicon.

10. The process for fabricating a lower electrode of a capacitor of claim 1, wherein the dielectric layer is made of silicon oxide.

11. A structure of a lower electrode of a capacitor applicable on a substrate on which a dielectric layer having at least a node contact opening to expose a part of conductive portion on the substrate is formed, comprising:
a node contact which is formed in the node contact opening and in electric contact with the conductive portion, wherein the node contact protrudes from the dielectric layer;
a protruding part positioned on a part of the node contact and a part of the dielectric layer;
a conductive layer located on the protruding part;
a link layer located on the dielectric layer outside the node contact to link the dielectric layer and the protruding part, the link layer being formed of the same material with the protruding part and integrated with the protruding part; and
a conductive spacer located on a sidewall of the conductive layer and the protruding part, which is in electric contact with the node contact and combined with the conductive layer as a lower electrode.

12. The structure of a lower electrode of a capacitor of claim 11, wherein a surface of the lower electrode further has a plurality of hemispherical silicon grains.

13. The structure of a lower electrode of a capacitor of claim 11, wherein the conductive portion includes a source/drain region which is a part of a metal oxide semiconductor.

14. The structure of a lower electrode of a capacitor of claim 11, wherein the conductive portion includes a landed via in electric contact with a source/drain region which is a part of a metal oxide semiconductor.

15. The structure of a lower electrode of a capacitor of claim 11, wherein the node contact is made of polysilicon.

16. The structure of a lower electrode of a capacitor of claim 11, wherein the protruding part and the link layer are made of silicon oxide.

17. The structure of a lower electrode of a capacitor of claim 11, wherein the conductive layer is made of polysilicon.

18. The structure of a lower electrode of a capacitor of claim 11, wherein the conductive spacer is made of polysilicon.
